(19) United States
(12) Patent Application Publication
(10) Pub. No.: US 2014/0087567 A1
(43) Pub. Date: Mar. 27, 2014

(54) SUBSTRATE PROCESSING APPARATUS AND METHOD OF MANUFACTURING SEMICONDUCTOR DEVICE

(71) Applicant: Hitachi Kokusai Electric Inc., Tokyo (JP)

(72) Inventors: Kazuyuki TOYODA, Toyama-shi (JP); Osamu KASAHARA, Tokyo (JP); Tetsuaki INADA, Imizu-shi (JP); Junichi TANABE, Toyama-shi (JP); Tatsushi UEDA, Toyama-shi (JP)

(73) Assignee: Hitachi Kokusai Electric Inc., Tokyo (JP)

(21) Appl. No.: 14/039,394

(22) Filed: Sep. 27, 2013

(30) Foreign Application Priority Data
Sep. 27, 2012 (JP) 2012-214275
Aug. 20, 2013 (JP) 2013-170571

(51) Int. Cl. C23C 16/44; H01L 21/02

(52) U.S. Cl. CPC C23C 16/44; H01L 21/02263
USPC 438/782; 118/719

(57) ABSTRACT

Provided is a substrate processing apparatus including: a substrate mounting portion provided in a process chamber and capable of mounting a plurality of substrates in a circumferential direction; a rotating mechanism that rotates the substrate mounting portion at a predetermined angular velocity; dividing structures provided in a radial form from a center of a lid of the process chamber so as to divide the process chamber into a plurality of areas; and gas supply areas disposed between the adjacent dividing structures, wherein an angle between the adjacent dividing structures with one gas supply area interposed is set to an angle corresponding to the angular velocity and a period in which a portion of the substrate mounting portion passes through the gas supply area.

### BACKGROUND

1. Technical Field

The present invention relates a substrate processing apparatus for forming a thin film on a surface of a processing substrate such as a silicon wafer while heating the processing substrate in a semiconductor device creating step, a lid mounted on the substrate processing apparatus, and a method of manufacturing the semiconductor device.

2. Related Art

For example, when a semiconductor device such as a flash memory or a dynamic random access memory (DRAM) is manufactured, a substrate processing step of forming a thin film on a substrate is often performed.

In the thin film forming step, various processing conditions are set according to a type and a thickness of the thin film to be formed. The processing conditions include a substrate temperature, a gas type, a substrate processing period, a process chamber pressure, and the like, for example.

As an example of a substrate processing apparatus that performs one of the steps of forming a thin film on a substrate, a thin-film deposition apparatus capable of forming a thin film simultaneously on a plurality of substrates mounted on a substrate mounting stage (for example, see JP 2008-524842 W).

This thin-film deposition apparatus includes a process chamber that is evenly divided into a plurality of processing areas and different types of gases are supplied to the respective areas. The plurality of substrates passes through the plurality of divided processing areas in the substrate processing apparatus, whereby a thin film is formed on the substrates.

### SUMMARY

However, in the thin-film deposition apparatus described above, the substrate processing period which is one of the processing conditions is constant in the respective processing areas. Thus, for example, when substrates of which the processing time is different in the respective processing areas are processed, it is difficult to form a desired film. Therefore, an object of the present invention is to provide a substrate processing apparatus capable of coping with a case where the processing time in the respective processing areas is different, a lid mounted on the substrate processing apparatus, and a method of manufacturing a semiconductor device.

According to an aspect of the present invention, there is provided a substrate processing apparatus including: a substrate mounting portion provided in a process chamber and capable of mounting a plurality of substrates in a circumferential direction; a rotating mechanism that rotates the substrate mounting portion at a predetermined angular velocity; dividing structures provided in a radial form from a center of a lid of the process chamber so as to divide the process chamber into a plurality of areas; and gas supply areas disposed between the adjacent dividing structures, wherein an angle between the adjacent dividing structures with one gas supply area interposed is set to an angle corresponding to the angular velocity and a period in which a portion of the substrate mounting portion passes through the gas supply area.

According to another aspect of the present invention, there is provided a lid mounted on a process chamber having a rotatable substrate mounting portion on which a plurality of substrates is mounted, including: a circular plate; and dividing structures provided in a radial form from a center of a lid of the process chamber so as to divide the process chamber into a plurality of gas supply areas when mounted on the process chamber, wherein an angle between the adjacent dividing structures with one gas supply area interposed is set to an angle corresponding to a period in which a portion of the substrate mounting portion passes through the gas supply area and an angular velocity of rotation of the substrate mounting portion.

According to another aspect of the present invention, there is provided a method of manufacturing a semiconductor device including: loading a plurality of substrates into a process chamber which includes processing areas divided by dividing structures provided in a radial form from a center of a lid of the process chamber and a rotatable substrate mounting portion on which the plurality of substrates is mounted, in which an angle between the adjacent dividing structures with one gas supply area interposed is set to an angle corresponding to the angular velocity and a period in which a portion of the substrate mounting portion passes through the gas supply area; placing the plurality of substrates on the substrate mounting portion; supplying gas to the processing areas while rotating the substrate mounting portion; and unloading the substrate from the process chamber.

According to the present invention, it is possible to provide a substrate processing apparatus capable of coping with a case where the processing time in the respective processing areas is different, a lid mounted on the substrate processing apparatus, and a method of manufacturing a semiconductor device.

### BRIEF DESCRIPTION OF THE DRAWINGS

FIG. 1 is a schematic cross-sectional view of a cluster-type substrate processing apparatus according to an embodiment of the present invention;

FIG. 2 is a schematic perspective view of a reaction container according to an embodiment of the present invention;

FIG. 3 is a schematic cross-sectional view of a processing furnace according to an embodiment of the present invention;

FIG. 4 is a schematic longitudinal cross-sectional view of the processing furnace according to an embodiment of the present invention and is a cross-sectional view along line A-A′ of the processing furnace illustrated in FIG. 3;

FIG. 5 is a schematic view illustrating a structure of a comb-shaped electrode as a plasma generating unit that changes processing gas supplied from a processing gas supply unit according to an embodiment of the present invention into plasma;

FIG. 6 is a schematic view illustrating a structure of a controller of a substrate processing apparatus according to an embodiment of the present invention;

FIG. 7 is a cross-sectional view of a processing furnace according to an embodiment of the present invention;

FIG. 8 is a view illustrating the processing time in a gas supply area according to an embodiment of the present invention;

FIG. 9 is a flowchart illustrating a substrate processing step according to a first embodiment of the present invention;

FIG. 10 is a flowchart illustrating processing on a substrate in a film forming step of the substrate processing step according to the first embodiment of the present invention;

FIG. 11 is a cross-sectional view of a processing furnace according to another embodiment of the present invention;

FIG. 12 is a view of a shower head according to another embodiment of the present invention;

FIG. 13 is a cross-sectional view of a processing furnace according to Comparative Example;

FIG. 14 is a longitudinal cross-sectional view of the processing furnace according to Comparative Example;

FIG. 15 is a cross-sectional view illustrating a gas supply state in the processing furnace according to Comparative Example; and

FIG. 16 is a view illustrating the processing time in a gas supply area according to Comparative Example.

### DETAILED DESCRIPTION

Hereinafter, an embodiment of the present invention will be described with reference to the drawings.

### (1) Structure of Substrate Processing Apparatus

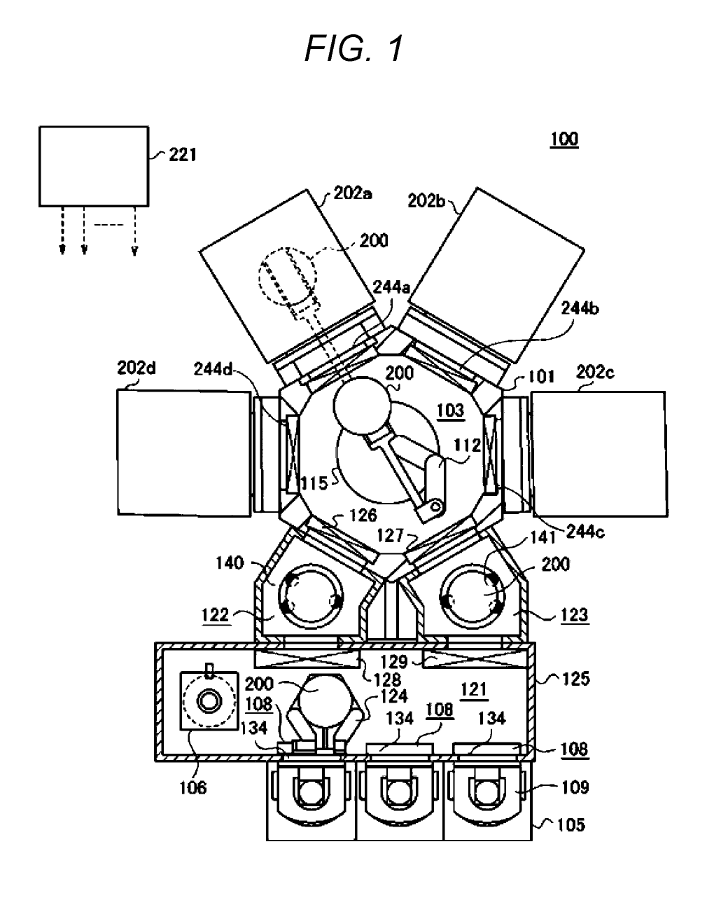

FIG. 1 is a cross-sectional view of a cluster-type substrate processing apparatus according to the present embodiment. In a substrate processing apparatus to which the present invention is applied, a front opening unified pod (FOUP, hereinafter referred to as a pod) is used as a carrier that transfers a substrate 200 as a semiconductor substrate. A transfer device of the cluster-type substrate processing apparatus according to the present embodiment is divided into a vacuum side and an atmosphere side. In this specification, the term “vacuum” refers to an industrial vacuum. Moreover, for convenience of explanation, a direction from a vacuum transfer chamber 103 to an atmosphere transfer chamber 121 in FIG. 1 is referred to as a front side.

### (Vacuum-Side Structure)

A cluster-type substrate processing apparatus 100 includes the vacuum transfer chamber 103 as a first transfer chamber that is configured as a load lock chamber structure whose internal pressure can be reduced to a pressure (for example, 100 Pa) less than atmospheric pressure such as a vacuum state. A housing 101 of the vacuum transfer chamber 103 has a hexagonal shape in a plan view thereof and has a box shape of which both upper and lower ends are closed, for example.

Load lock chambers 122 and 123 are provided in two side walls located on the front side, among the six side walls that form the housing 101 of the vacuum transfer chamber 103 so as to communicate with the vacuum transfer chamber 103 with gate valves 126 and 127 interposed, respectively.

Process chambers 202a and 202b are provided in two side walls among the other four side walls of the vacuum transfer chamber 103 so as to communicate with the vacuum transfer chamber 103 with gate valves 244a and 244b interposed, respectively. A processing gas supply unit, an inert gas supply unit, an exhaust unit, and the like described later are provided in the process chambers 202a and 202b. In the process chambers 202a and 202b, a plurality of processing areas and the same number of purge areas as the processing areas are alternately arranged in one reaction container as will be described later. Moreover, a susceptor (also referred to as a substrate mounting portion or a rotating tray) 217 as a substrate support member provided in the reaction container 203 is rotated so that the substrate 200 as a substrate passes through the processing area and the purge area alternately. Due to such a structure, processing gas and inert gas are alternately supplied to the substrate 200 and the following substrate processes are performed. Specifically, various substrate processes such as a process of forming a thin film on the substrate 200, a process of oxidizing, nitriding, and carbonizing the surface of the substrate 200, and a process of etching the surface of the substrate 200 are performed.

Cooling chambers 202c and 202d are provided in the remaining two side walls of the vacuum transfer chamber 103 so as to communicate with the vacuum transfer chamber 103 with gate valves 244c and 244d interposed, respectively.

A vacuum transfer robot 112 as a first transfer mechanism is provided in the vacuum transfer chamber 103. The vacuum transfer robot 112 is configured to transfer two substrates 200 (indicated by dot line in FIG. 1) simultaneously, for example, between the load lock chambers 122 and 123, the process chambers 202a and 202b, and the cooling chambers 202c and 202d. The vacuum transfer robot 112 is configured to be moved up and down by an elevator 115 while maintaining air-tightness of the vacuum transfer chamber 103. Moreover, a substrate detection sensor (not illustrated) that detects the presence of the substrate 200 is provided near each of the gate valves 126 and 127 of the load lock chambers 122 and 123, the gate valves 244a and 244b of the process chambers 202a and 202b, and the gate valves 244c and 244d of the cooling chambers 202c and 202d. The substrate detection sensor is also referred to as a substrate detection unit.

The load lock chambers 122 and 123 are configured as a load lock chamber structure whose internal pressure can be reduced to a pressure (reduced pressure) less than atmospheric pressure such as a vacuum state. That is, an atmosphere transfer chamber 121 as a second transfer chamber described later is provided on the front side of the load lock chamber with gate valves 128 and 129 interposed. Due to this, after the gate valves 126 to 129 are closed to evacuate the inside of the load lock chambers 122 and 123, the gate valves 126 and 127 are open, whereby the substrate 200 can be transferred between the load lock chambers 122 and 123 and the vacuum transfer chamber 103 while maintaining the vacuum state of the vacuum transfer chamber 103. Moreover, the load lock chambers 122 and 123 function as an auxiliary chamber that temporarily receives the substrate 200 that is loaded into the vacuum transfer chamber 103. In this case, the substrate 200 is mounted on the substrate mounting portion 140 in the load lock chamber 122 and on the substrate mounting portion 141 in the load lock chamber 123.

### (Atmosphere-Side Structure)

The atmosphere transfer chamber 121 as a second transfer chamber that is used under substantial atmospheric pressure is provided on an atmosphere side of the substrate processing apparatus 100. That is, the atmosphere transfer chamber 121 is provided on the front side of the load lock chambers 122 and 123 (different side of the vacuum transfer chamber 103) with the gate valves 128 and 129 interposed. The atmosphere transfer chamber 121 is provided so as to be communicable with the load lock chambers 122 and 123.

An atmosphere transfer robot 124 as a second transfer mechanism that transfers the substrate 200 so as to be mounted is provided in the atmosphere transfer chamber 121. The atmosphere transfer robot 124 is configured to be moved up and down by an elevator (not illustrated) provided in the atmosphere transfer chamber 121 and is configured to reciprocate in the left-right direction by a linear actuator (not illustrated). Moreover, a substrate detection sensor (not illustrated) that detects the presence of the substrate 200 is provided near the gate valves 128 and 129 of the atmosphere transfer chamber 121. The substrate detection sensor is also referred to as a substrate detection unit.

Moreover, a notch aligner 106 as a position correcting device of the substrate 200 is provided in the atmosphere transfer chamber 121. The notch aligner 106 determines a crystalline direction, a positional alignment, and the like of the substrate 200 with a notch formed in the substrate 200 and corrects the position of the substrate 200 based on the determined information. An orientation flat aligner (not illustrated) may be provided instead of the notch aligner 106. Moreover, a clean unit (not illustrated) that supplies clean air is provided above the atmosphere transfer chamber 121.

A substrate transfer opening 134 through which the substrate 200 is transferred into and out of the atmosphere transfer chamber 121 and a pod opener 108 are provided on the front side of the housing 125 of the atmosphere transfer chamber 121. A load port (I/O stage) 105 is provided on a side opposite to the pod opener 108 (that is, on the outer side of the housing 125) with the substrate transfer opening 134 interposed. A pod 109 that receives a plurality of substrates 200 is mounted on the load port 105. Moreover, a lid 135 that opens and closes the substrate transfer opening 134, an opening/closing mechanism 143 that opens and closes a cap or the like of the pod 109, and an opening/closing mechanism driving unit 136 that drives the opening/closing mechanism 143 are provided in the atmosphere transfer chamber 121. The pod opener 108 opens and closes the cap of the pod 109 mounted on the load port 105 so that the substrate 200 can be loaded into and unloaded from the pod 109. Moreover, the pod 109 is loaded (supplied) into and unloaded (discharged) from the load port 105 by a transfer device (RGV) (not illustrated).

The transfer device of the substrate processing apparatus 100 according to the present embodiment mainly includes the vacuum transfer chamber 103, the load lock chambers 122 and 123, the atmosphere transfer chamber 121, and the gate valves 126 to 129.

Moreover, a control unit 221 described later is electrically connected to the respective constituent components of the transfer device of the substrate processing apparatus 100. The control unit 221 controls the operation of the respective constituent components.

### (Substrate Transfer Operation)

Next, an operation of transferring the substrate 200 in the substrate processing apparatus 100 according to the present embodiment will be described. The operation of the respective constituent components of the transfer device of the substrate processing apparatus 100 is controlled by the control unit 221.

First, the pod 109 in which 25 pieces of unprocessed substrates 200, for example, are received is loaded into the substrate processing apparatus 100 by the transfer device (not illustrated). The loaded pod 109 is mounted on the load port 105. The opening/closing mechanism 143 removes the lid 135 and the cap of the pod 109 and opens the substrate transfer opening 134 and a substrate entrance opening of the pod 109.

When the substrate entrance opening of the pod 109 is opened, the atmosphere transfer robot 124 provided in the atmosphere transfer chamber 121 picks up one substrate 200 from the pod 109 and mounts the substrate 200 on the notch aligner 106.

The notch aligner 106 moves the mounted substrate 200 in horizontally longitudinal and lateral directions (X and Y-directions) and a circumferential direction to adjust a notch position and the like of the substrate 200. When the position of a first substrate 200 is adjusted by the notch aligner 106, the atmosphere transfer robot 124 picks up a second substrate 200 from the pod 109, loads the substrate 200 into the atmosphere transfer chamber 121, and waits in the atmosphere transfer chamber 121.

After the position of the first substrate 200 is adjusted by the notch aligner 106, the atmosphere transfer robot 124 picks up the first substrate 200 on the notch aligner 106. The atmosphere transfer robot 124 causes the second substrate 200 held by the atmosphere transfer robot 124 at that time to be mounted on the notch aligner 106. After that, the notch aligner 106 adjusts the notch position and the like of the second substrate 200 mounted.

Subsequently, the gate valve 128 is opened, and the atmosphere transfer robot 124 loads the first substrate 200 into the load lock chamber 122 and mounts the substrate 200 on the substrate mounting portion 140. During this transferring and mounting operation, the gate valve 126 close to the vacuum transfer chamber 103 is closed and a reduced-pressure atmosphere in the vacuum transfer chamber 103 is maintained. When the transferring and mounting the first substrate 200 on the substrate mounting portion 140 is completed, the gate valve 128 is closed, and the inside of the load lock chamber 122 is exhausted by an exhaust device (not illustrated) so that a negative pressure state is created.

After that, the atmosphere transfer robot 124 repeats the above-described operation. However, when the load lock chamber 122 is in the negative pressure state, the atmosphere transfer robot 124 does not load the substrate 200 into the load lock chamber 122 but stops and waits at the previous position in the load lock chamber 122.

When the internal pressure of the load lock chamber 122 is reduced to a predetermined pressure value (for example, 100 Pa), the gate valve 126 is opened so that the load lock chamber 122 communicates with the vacuum transfer chamber 103. Subsequently, the vacuum transfer robot 112 disposed in the vacuum transfer chamber 103 picks up the first substrate 200 from the substrate mounting portion 140 and loads the substrate 200 into the vacuum transfer chamber 103.

After the vacuum transfer robot 112 picks up the first substrate 200 from the substrate mounting portion 140, the gate valve 126 is closed, the internal pressure of the load lock chamber 122 returns to an atmospheric pressure, and preparations for loading the next substrate 200 into the load lock chamber 122 are performed. In parallel with this, the gate valve 244a of the process chamber 202a at a predetermined pressure (for example, 100 Pa) is opened, and the vacuum transfer robot 112 loads the first substrate 200 into the process chamber 202a. This operation is repeated until an optional number of (for example, five) substrates 200 are loaded into the process chamber 202a. When loading of an optional number of (for example, five) substrates 200 into the process chamber 202a is completed, the gate valve 244a is closed. After that, a processing gas is supplied into the process chamber 202a from a gas supply unit described later, and a predetermined process is performed on the substrate 200.

When a predetermined process is performed on the process chamber 202a and the substrate 200 is cooled in the process chamber 202a as will be described later, the gate valve 244a is opened. After that, the processed substrate 200 is unloaded from the process chamber 202a into the vacuum transfer chamber 103 by the vacuum transfer robot 112. After the substrate 200 is unloaded, the gate valve 244a is closed.

Subsequently, the gate valve 127 is opened, and the substrate 200 unloaded from the process chamber 202a is loaded into the load lock chamber 123 and mounted on the substrate mounting portion 141. The internal pressure of the load lock chamber 123 is reduced to a predetermined pressure value by an exhaust device (not illustrated). After that, the gate valve 127 is closed, inert gas is introduced from an inert gas supply unit (not illustrated) connected to the load lock chamber 123, and the internal pressure of the load lock chamber 123 returns to the atmospheric pressure.

When the internal pressure of the load lock chamber 123 returns to the atmospheric pressure, the gate valve 129 is opened. Subsequently, after the atmosphere transfer robot 124 picks up the processed substrate 200 on the substrate mounting portion 141 and unload the substrate 200 into the atmosphere transfer chamber 121, the gate valve 129 is closed. After that, the atmosphere transfer robot 124 causes the processed substrate 200 to be received in the pod 109 through the substrate transfer opening 134 of the atmosphere transfer chamber 121. Here, the cap of the pod 109 may be open until a maximum of 25 substrates 200 are returned, and the substrate may not be received in an empty pod 109 but may be returned to a pod from which the substrate is unloaded.

When a predetermined process is performed on all substrates 200 in the pod 109 by the above-described step and all of the 25 pieces of processed substrates 200 are received in a predetermined pod 109, the cap of the pod 109 and the lid 135 of the substrate transfer opening 134 are closed by the opening/closing mechanism 143. After that, the pod 109 is transferred from the load port 105 to the next step by a transfer device (not illustrated). The above operation is repeated, whereby a plurality of sets of substrates 200 each including 25 pieces of substrates is processed sequentially.

### (2) Structure of Process Chamber

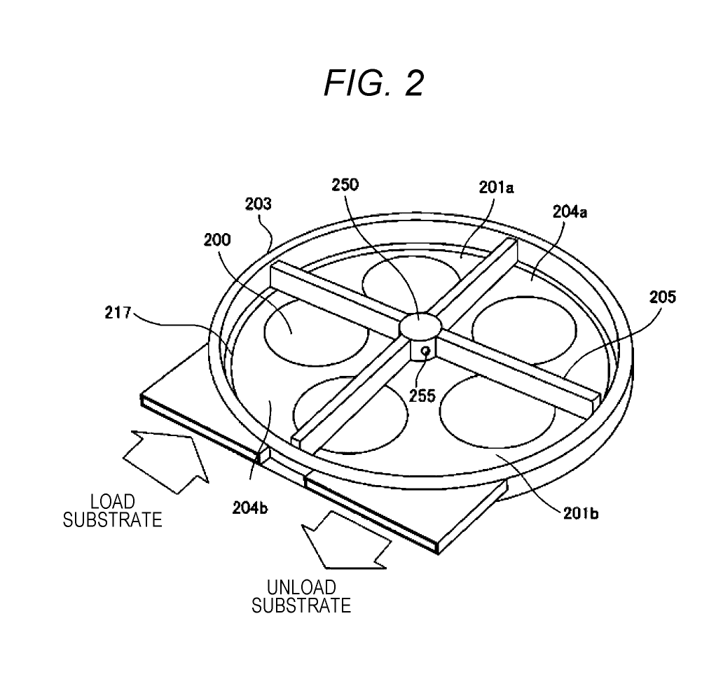

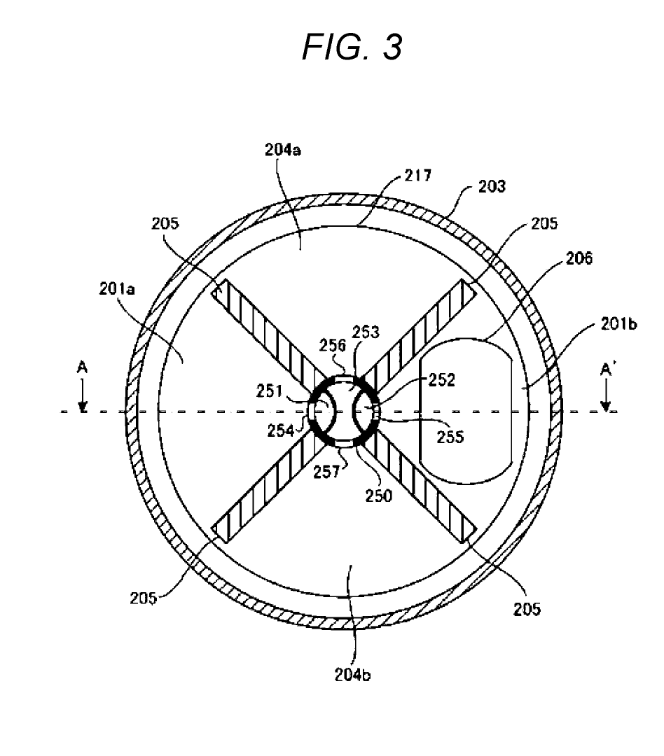

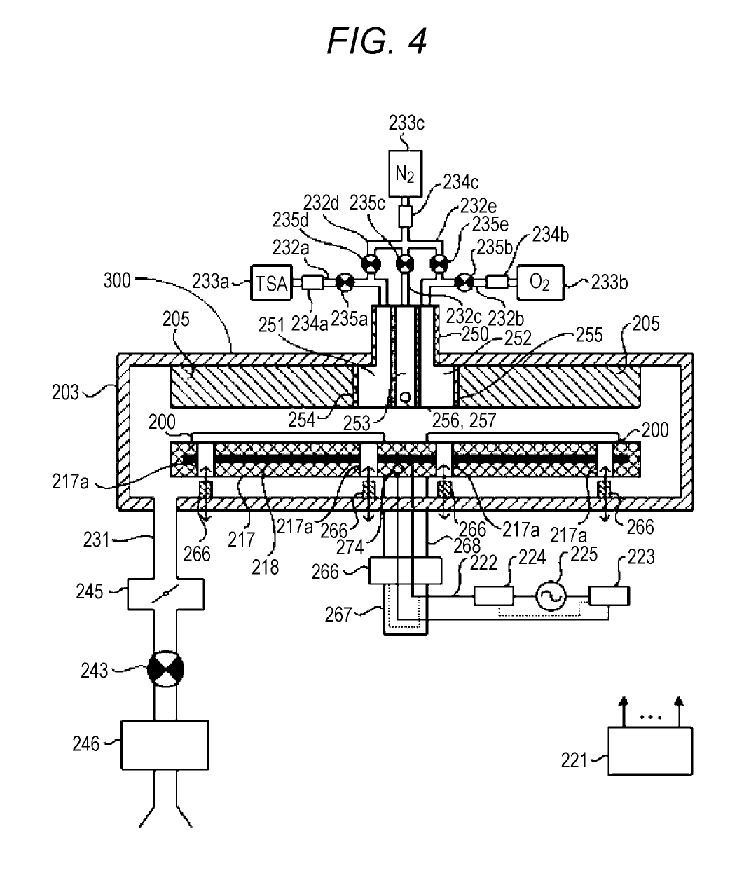

Next, the structure of the process chamber 202a as a processing furnace according to the present embodiment will be described mainly with reference to FIGS. 2 to 4. FIG. 2 is a schematic perspective view of a reaction container according to the present embodiment. FIG. 3 is a schematic cross-sectional view of the processing furnace according to the present embodiment. FIG. 4 is a schematic longitudinal cross-sectional view of the processing furnace according to the present embodiment and is a cross-sectional view along line A-A′ of the processing furnace illustrated in FIG. 3. The process chamber 202b has the same structure as the process chamber 202a and description thereof will not be provided.

### (Reaction Container)

As illustrated in FIGS. 2 to 4, the process chamber 202a as a processing furnace includes a reaction container 203 which is a cylindrical air-tight container. A processing space for the substrate 200 is formed in the reaction container 203. Four partition plates 205 are provided on the upper side of the processing space in the reaction container 203 so as to extend in a radial form from a central portion of the reaction container 203.

The four partition plates (dividing structures) 205 are configured such that the processing space in the reaction container 203 is partitioned (divided) into a first processing area 201a, a first purge area 204a, a second processing area 201b, and a second purge area 204b. That is, the four partition plates 205 are used as dividing structures that divide the inside of the reaction container 203 into the first processing area 201a, the first purge area 204a, the second processing area 201b, and the second purge area 204b. Preferably, at least two dividing structures may be formed so that the processing space is divided into at least two processing areas. The partition plates 205 are attached to a circular plate 300 that serves as a lid of the reaction container 203 so as to extend in a radial form from the center of the circular plate 300.

The first processing area 201a, the first purge area 204a, the second processing area 201b, and the second purge area 204b are configured so that the areas are arranged in that order along the rotation direction of the susceptor 217 described later (that is, so that the processing area and the purge area are arranged alternately). In other words, the first processing area 201a, the first purge area 204a, the second processing area 201b, and the second purge area 204b which are gas supply areas are disposed between adjacent dividing structures.

As will be described later, when the susceptor 217 is rotated, the substrate 200 mounted on the susceptor 217 is moved so as to pass through the first processing area 201a, the first purge area 204a, the second processing area 201b, and the second purge area 204b in that order. Moreover, as will be described later, a first processing gas as first gas is supplied into the first processing area 201a, a second processing gas as second gas is supplied into the second processing area 201b, and an inert gas is supplied into the first and second purge areas 204a and 204b. Due to this, when the susceptor 217 is rotated, the first processing gas, the inert gas, the second processing gas, and the inert gas are supplied to the substrate 200 in that order. The structures of the susceptor 217 and a gas supply system will be described later.

A gap with a predetermined width is formed between an end of the partition plate 205 and a side wall of the reaction container 203 so that gas can pass through this gap. Through this gap, the inert gas is injected from the first and second purge areas 204a and 204b into the first and second processing areas 201a and 201b. By doing so, it is possible to prevent the processing gas from entering into the first and second purge areas 204a and 204b and to prevent reaction of the processing gas and production of foreign substance by the reaction.

(susceptor)

As illustrated in FIGS. 2 to 4, the susceptor 217 of which the center of the rotation axis is at the center of the reaction container 203 and which is configured to rotate at a desired angular velocity is provided under the partition plate 205 (that is, at the center on the bottom side of the reaction container 203). The susceptor 217 is also referred to as a substrate support member. The susceptor 217 is formed from a non-metallic material such as, for example, aluminum nitride (AlN), ceramics, or quartz so that metallic contamination of the substrate 200 can be reduced. The susceptor 217 is electrically isolated from the reaction container 203. The lid 300 that functions as a lid of the reaction container 203 is provided above the susceptor 217 so as to face the susceptor 217. The lid 300 is configured so as to be removable and the partition plates 205 are attached thereto.

The susceptor 217 is configured so that a plurality of (for example, five in the present embodiment) substrates 200 is supported so as to be arranged on the same surface and on the same circumference in the reaction container 203. Here, the same surface is not limited to completely the same surface. For example, when the susceptor 217 is viewed from the upper surface, as illustrated in FIGS. 2 and 3, a plurality of substrates 200 may be arranged so as not to overlap with each other.

A circular concave portion (not illustrated) may be formed at a position of the surface of the susceptor 217 where the substrate 200 is supported. This concave portion preferably has a diameter slightly larger than the diameter of the substrate 200. By placing the substrate 200 in the concave portion, the positioning of the substrate 200 can be performed easily. Moreover, although centrifugal force is applied to the substrate 200 when the susceptor 217 rotates, a positional deviation of the substrate 200 due to the centrifugal force can be prevented by placing the substrate 200 in the concave portion.

As illustrated in FIG. 4, a lifting mechanism 268 that moves up and down the susceptor 217 is provided in the susceptor 217. A plurality of through-holes 217a is formed in the susceptor 217. A plurality of substrate lifting pins 266 is formed in the bottom surface of the reaction container 203. When the substrate 200 is loaded into and unloaded from the reaction container 203, the substrate lifting pins 266 lift the substrate 200 to support the rear surface of the substrate 200. The through-holes 217a and the substrate lifting pins 266 are arranged so that the substrate lifting pins 266 pass through the through-holes 217a without making contact with the susceptor 217 when the substrate lifting pins 255 are moved up or the susceptor 217 is moved down by the lifting mechanism 268.

A rotating mechanism 267 that rotates the susceptor 217 is provided in the lifting mechanism 268. A rotating shaft (not illustrated) of the rotating mechanism 267 is connected to the susceptor 217 and is configured to rotate the susceptor 217 when the rotating mechanism 267 is operated. The control unit 221 described later is connected to the rotating mechanism 267 with a coupling unit 267a interposed. The coupling unit 267a is configured as a slip ring mechanism that electrically connects a rotating side and a fixed side by a metal brush or the like. Due to this, rotation of the susceptor 217 is not disturbed. The control unit 221 is configured to control a conduction state of the rotating mechanism 267 so that the susceptor 217 rotates at a predetermined speed for a predetermined period. As described above, when the susceptor 217 rotates, the substrate 200 mounted on the susceptor 217 moves through the first processing area 201a, the first purge area 204a, the second processing area 201b, and the second purge area 204b in that order.

### (Heating Unit)

A heater 218 as a Heating unit is integrally embedded inside the susceptor 217 so as to heat the substrate 200. When electric power is supplied to the heater 218, the surface of the substrate 200 is heated to a predetermined temperature (for example, room temperature to about 1000° C.) A plurality of (for example, five) heaters 218 may be provided on the same surface so that the respective substrates 200 mounted on the susceptor 217 are heated individually.

A temperature sensor 274 is provided in the susceptor 217. A temperature controller 223, a power controller 224, and a heater power supply 225 are electrically connected to the heater 218 and the temperature sensor 274 through a power supply line 222. A conduction state of the heater 218 is controlled based on the temperature information detected by the temperature sensor 274.

### (Gas Supply Unit)

A gas supply mechanism 250 that includes a first processing gas introduction mechanism 251, a second processing gas introduction mechanism 252, and an inert gas introduction mechanism 253 is provided above the reaction container 203. The gas supply mechanism 250 is formed air-tightly in an opening that is formed on the upper side of the reaction container 203. A first gas injection hole 254 is formed in the side wall of the first processing gas introduction mechanism 251. A second gas injection hole 255 is formed in the side wall of the second processing gas introduction mechanism 252. First and second inert gas injection holes 256 and 257 are formed in the side wall of the inert gas introduction mechanism 253 so as to face each other. The gas supply mechanism 250 is configured so that the first processing gas is supplied from the first processing gas introduction mechanism 251 into the first processing area 201a, the second processing gas is supplied from the second processing gas introduction mechanism 252 into the second processing area 201b, and the inert gas is supplied from the inert gas introduction mechanism 253 into the first and second purge areas 204a and 204b. The gas supply mechanism 250 can supply the respective processing gases and the inert gas individually so as not to mix with each other. Moreover, the gas supply mechanism 250 is configured to supply the respective processing gases and the inert gas in parallel.

### (Processing Gas Supply Unit)

A first gas supply pipe 232a is connected to the upstream side of the first processing gas introduction mechanism 251. A raw material gas supply source 233a, a mass flow controller (MFC) 234a which is a flow rate controller (flow rate control unit), and a valve 235a which is an opening/closing valve are provided on the upstream side of the first gas supply pipe 232a in that order from the upstream side.

A silicon-containing gas, for example, as a first gas (first processing gas) is supplied from the first gas supply pipe 232a into the first processing area 201a through the mass flow controller 234a, the valve 235a, the first processing gas introduction mechanism 251, and the first gas injection hole 254. Trisilylamine ((SiH₃)₃N, TSA) gas, for example can be used as the silicon-containing gas. Although the first processing gas may be in the state of any one of solid, liquid, and gas at a room temperature and a normal pressure, in this specification, it will be described that the first processing gas is in the gas state. When the first processing gas is in the state of liquid at a room temperature and a normal pressure, a vaporizer (not illustrated) may be provided between the raw material gas supply source 233a and the mass flow controller 234a.

In addition to TSA, for example, hexamethyldisilazane (C₆H₁₉NSi₂, HMDS), tris(dimethylamino)silane (Si[N(CH₃)₂]₃H, 3DMAS), bis(tertiary-butylamino)silane (SiH₂(NH(C₄H₉))₂, BTBAS), and the like which are organic silicon materials can be used as the silicon-containing gas.

A second gas supply pipe 232b is connected to the upstream side of the second processing gas introduction mechanism 252. A raw material gas supply source 233b, a mass flow controller (MFC) 234b which is a flow rate controller (flow rate control unit), and a valve 235b which is an opening/closing valve are provided on the upstream side of the second gas supply pipe 232b in that order from the upstream side.

An oxygen (O₂) gas which is an oxygen-containing gas, for example, as a second gas (second processing gas) is supplied from the second gas supply pipe 232b into the second processing area 201b through the mass flow controller 234b, the valve 235b, the second processing gas introduction mechanism 252, and the second gas injection hole 255. The oxygen gas which is the second processing gas is changed into a plasma by the plasma generating unit 206 described above and is supplied to the substrate 200. The oxygen gas which is the second processing gas may be activated by heat by adjusting the temperature of the heater 218 and the internal pressure of the reaction container 203 so as to fall within a predetermined range. An ozone (O₃) gas or vapor (H₂O) may be used as the oxygen-containing gas.

A first processing gas supply unit (also referred to as a silicon-containing gas supply system) mainly includes the first processing gas introduction mechanism 251, the first gas supply pipe 232a, the mass flow controller 234a, and the valve 235a. It may be understood that the first processing gas supply unit includes the raw material gas supply source 233a, the first processing gas introduction mechanism 251, and the first gas injection hole 254. Moreover, a second processing gas supply unit (also referred to as an oxygen-containing gas supply system) mainly includes the second processing gas introduction mechanism 252, the second gas supply pipe 232b, the mass flow controller 234b, and the valve 235b. It may be understood that the second processing gas supply unit includes the raw material gas supply source 233b, the second processing gas introduction mechanism 252, and the second gas injection hole 255. Moreover, a processing gas supply unit mainly includes the first and second gas supply systems. The first and second processing gas supply units are referred to as a processing gas supply unit.

### (Inert Gas Supply Unit)

A first inert gas supply pipe 232c is connected to the upstream side of the inert gas introduction mechanism 253. An inert gas supply source 233c, a mass flow controller (MFC) 234c which is a flow rate controller (flow rate control unit), and a valve 235c which is an opening/closing valve are provided on the upstream side of the first inert gas supply pipe 232c in that order from the upstream side.

A nitrogen (N₂) gas, for example, as an inert gas is supplied from the first inert gas supply pipe 232c into the first and second purge areas 204a and 204b through the mass flow controller 234c, the valve 235c, the inert gas introduction mechanism 253, and the first and second inert gas injection holes 256 and 257. The inert gas supplied to the first and second purge areas 204a and 204b acts as a purge gas in a film forming step (S106) described later. In addition to N₂ gas, rare gas such as He gas, Ne gas, or Ar gas can be used as the inert gas, for example.

A downstream end of the second inert gas supply pipe 232d is connected to a side closer to the downstream side than the valve 235a of the first gas supply pipe 232a. An upstream end of the second inert gas supply pipe 232d is connected between the mass flow controller 234c and the valve 235c of the first inert gas supply unit. A valve 235d which is an opening/closing valve is formed in the second inert gas supply pipe 232d.

Moreover, a downstream end of a third inert gas supply pipe 232e is connected to a side closer to the downstream side than the valve 235b of the second gas supply pipe 232b. The upstream end of the third inert gas supply pipe 232a is connected between the mass flow controller 234c and the valve 235c of the first inert gas supply unit. A valve 235e which is an opening/closing valve is formed in the third inert gas supply pipe 232e.

A N₂ gas, for example, as an inert gas is supplied from the third inert gas supply pipe 232e into the second processing area 201b through the mass flow controller 234c, the valve 235e, the second gas supply pipe 232b, the second processing gas introduction mechanism 252, and the second gas injection hole 255. The inert gas supplied into the second processing area 201b acts as a carrier gas or a diluent gas in the film forming step (S106) similarly to the inert gas supplied into the first processing area 201a.

A first inert gas supply unit mainly includes the first inert gas supply pipe 232c, the mass flow controller 234c, and the valve 235c. It may be understood that the first inert gas supply unit includes the inert gas supply source 233c, the inert gas introduction mechanism 253, and the first and second inert gas injection holes 256 and 257. Moreover, a second inert gas supply unit mainly includes the second inert gas supply pipe 232d and the valve 235d. It may be understood that the second inert gas supply unit includes the inert gas supply source 233c, the mass flow controller 234c, the first gas supply pipe 232a, the first processing gas introduction mechanism 251, and the first gas injection hole 254. Moreover, a third inert gas supply unit mainly includes the third inert gas supply pipe 232e and the valve 235e. It may be understood that the third inert gas supply unit includes the inert gas supply source 233c, the mass flow controller 234c, the second gas supply pipe 232b, the second processing gas introduction mechanism 252, and the second gas injection hole 255. Furthermore, an inert gas supply unit mainly includes the first, second, and third inert gas supply units.

### (Plasma Generating Unit)

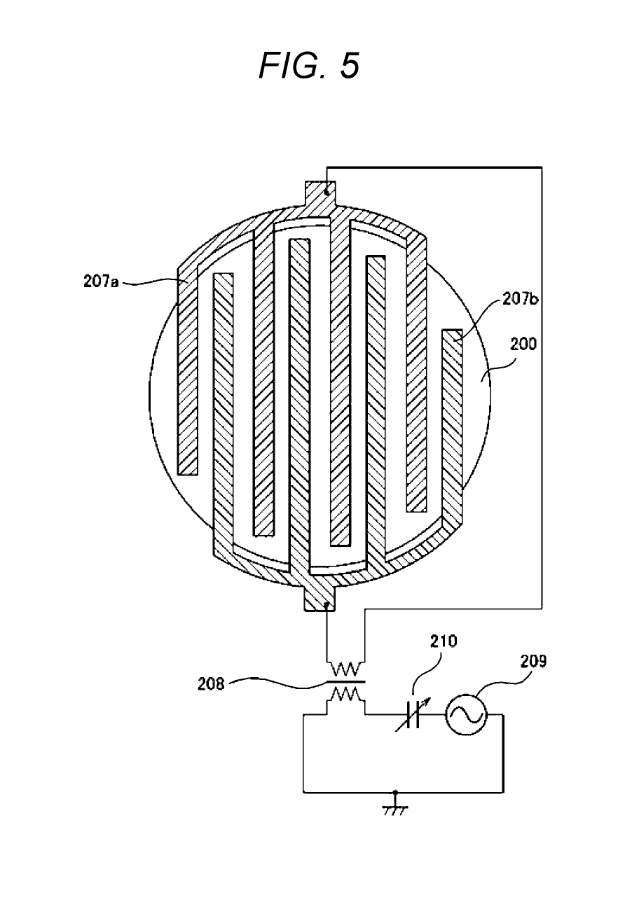

As illustrated in FIG. 3, the plasma generating unit 206 that changes the processing gas supplied into a plasma is provided above the second processing area 201b. By changing the processing gas into the plasma, the substrate 200 can be processed at a low temperature. As illustrated in FIG. 5, the plasma generating unit 206 includes at least a pair of facing comb-shaped electrodes 207a and 207b. A secondary-side output of an insulated transformer 208 is electrically connected to the comb-shaped electrodes 207a and 207b. When an AC power output from a high-frequency power supply 209 is supplied to the comb-shaped electrodes 207a and 207b through a matching circuit 210, a plasma is generated around the comb-shaped electrodes 207a and 207b.

The comb-shaped electrodes 207a and 207b are preferably disposed at a height of 5 mm or more and 25 mm or smaller from a processing surface of the substrate 200 supported by the susceptor 217 so as to face the processing surface of the substrate 200. In this manner, when the comb-shaped electrodes 207a and 207b are provided very closely to the processing surface of the substrate 200, it is possible to suppress the activated processing gas from being deactivated before the gas reaches the substrate 200.

The number, width, and interval of the comb-shaped electrodes 207a and 207b can be appropriately changed according to processing conditions and the like. Moreover, the structure of the plasma generating unit 206 is not limited to the above structure in which the comb-shaped electrodes 207a and 207b are included in the second processing area 201b. That is, the plasma generating unit 206 may only need to supply a plasma to the processing surface of the substrate 200 supported on the susceptor 217 and may be a remote plasma mechanism that is provided in the midway of the processing gas supply unit. When the remote plasma mechanism is used, it is possible to decrease the second processing area 201b.

The plasma generating unit includes at least a pair of facing comb-shaped electrodes 207a and 207b, and mainly includes the comb-shaped electrodes 207a and 207b, the insulated transformer 208, and the matching circuit 210. The plasma generating unit may include the high-frequency power supply 209.

### (Exhaust Unit)

As illustrated in FIG. 4, an exhaust pipe 231 that exhausts the atmosphere in the processing areas 201a and 201b and the atmosphere in the purge areas 204a and 204b is provided in the reaction container 203. A vacuum pump 246 which is a vacuum exhaust device is connected to the exhaust pipe 231 through a pressure sensor 245 which is a pressure detector (pressure detection unit) that detects the internal pressure of the reaction container 203 (the processing areas 201a and 201b and the purge areas 204a and 204b) and an auto pressure controller (APC) valve 243 which is a pressure controller (pressure adjustment unit). The inside of the reaction container 203 can be evacuated so that the internal pressure becomes a predetermined pressure (degree of vacuum). Moreover, the APC valve 243 is an opening/closing value capable of evacuating the reaction container 203 and stopping the evacuating by opening and closing the valve and adjusting the pressure by controlling the degree of the valve opening. An exhaust unit mainly includes the exhaust pipe 231, the APC valve 243, and the pressure sensor 245. It may be understood that the exhaust unit includes the vacuum pump 246.

### (Control Unit)

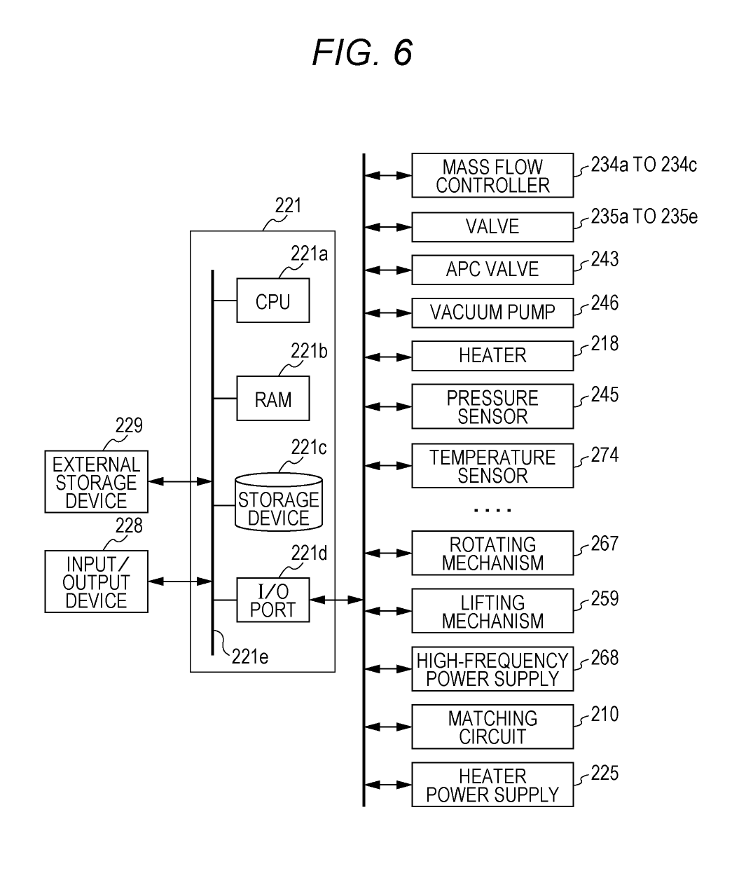

As illustrated in FIG. 6, the controller 221 that is a control unit (control means) is configured as a computer that includes a central processing unit (CPU) 221a, a random access memory (RAM) 221b, a storage device 221c, and an I/O port 221d. The RAM 221b, the storage device 221c, and the I/O port 221d are configured to exchange data with the CPU 221a via an internal bus 221e. An input/output device 228 configured as a touch panel or the like, for example, is connected to the controller 221.

The storage device 221c is configured as a flash memory, a hard disk drive (HDD), or the like, for example. A control program that controls the operation of the substrate processing apparatus 100, a process recipe in which substrate processing procedures described later, processing conditions, and the like are described, and the like are stored in the storage device 221c so as to be readable. Moreover, the process recipe is combined to obtain a predetermined result by causing the controller 221 to execute procedures of a substrate processing step described later and functions as a program. Hereinafter, the process recipe, a control program, and the like are collectively referred to simply as a program. Moreover, a case where the term “program” is used in this specification may include a case where the program includes a process recipe only, a case where the program includes a control program only, or a case where the program includes both the process recipe and the control program. Moreover, the RAM 221b is configured as a memory area (work area) in which the program or data read by the CPU 221a is temporarily stored.

The I/O port 221d is connected to the mass flow controllers 234a, 234b, and 234c, the valves 235a, 235b, 235c, 235d, and 235e, the pressure sensor 245, the APC valve 243, the vacuum pump 246, the heater 218, the temperature sensor 274, the rotating mechanism 267, the lifting mechanism 268, the high-frequency power supply 209, the matching circuit 210, the heater power supply 225, and the like.

The CPU 221a is configured to read the control program from the storage device 221c and execute the control program and to read the process recipe from the storage device 221c according to an input of an operation command from the input/output device 228. The CPU 221a is configured to control various operations according to the content of the read process recipe. Specifically, the CPU 221a controls the operations of the mass flow controllers 234a, 234b, and 234b controlling the flow rate of various types of gases, the operation of opening and closing the valves 235a, 235b, 235c, 235d, and 235e, the operation of opening and closing the APC valve 243, the pressure controlling operation based on the pressure sensor 245, the operation of controlling the temperature of the heater 218 based on the temperature sensor 274, the operation of starting and stopping the vacuum pump 246, the operation of controlling the rotation speed of the rotating mechanism 267, the lifting operation of the lifting mechanism 268, the supply of electric power of the high-frequency power supply 209, the supply of electric power of the heater power supply 225, and the operation of the matching circuit 210 controlling the impedance.

Moreover, the controller 221 is not limited to being configured as a dedicated computer but may be configured as a general-purpose computer. For example, the controller 221 according to the present embodiment may be configured by preparing an external storage device 229 (for example, a magnetic tape, a magnetic disk such as a flexible disk or a hard disk, an optical disc such as a CD or a DVD, a magneto-optical disc such as an MO, or a semiconductor memory such as a USB memory or a memory card) that stores the above-described program and installing the program in a general-purpose computer using the external storage device 229. Moreover, the means for supplying a program to a computer is not limited to a case where the program is supplied by means of the external storage device 229. For example, a program may be supplied using communication means such as Internet or a dedicated line, without using the external storage device 229. Moreover, the storage device 221c or the external storage device 229 is configured as a computer-readable recording medium. Hereinafter, these storage devices will be collectively referred to simply as a recording medium. Moreover, a case where the term “recording medium” is used in this specification may include a case where the recording medium includes only the storage device 221c, a case where the recording medium includes only the external storage device 229, or a case where the recording medium includes both the storage device 221c and the external storage device 229.

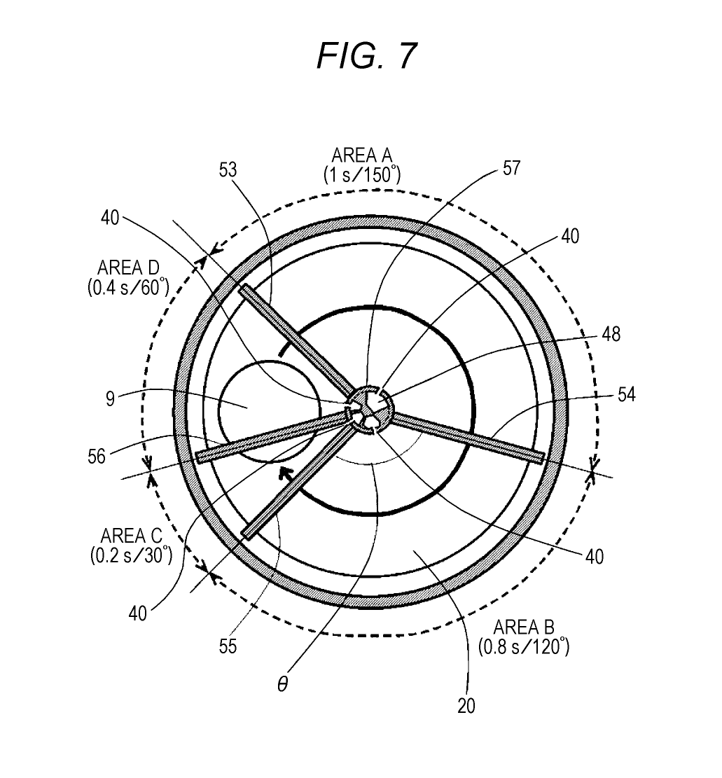

Next, the relationship between the lid according to the embodiment of the present invention, the dividing structures (partition plates), the angular velocity of the rotating susceptor, and the processing time in each region will be described in detail with reference to FIG. 7. In this description, for convenience of explanation, the plasma generating unit will not be mentioned. In addition, in this description, for convenience of explanation, the respective constituent components will be referred to as follows. Specifically, the first processing area 201a, the first purge area 204a, the second processing area 201b, and the second purge area 204b as the gas supply areas will be referred to as gas supply areas A, B, C, and D, respectively. Similarly, the four partition plates (dividing structures) 205 will be referred to as partition plates 53, 54, 55, and 56. Similarly, the substrate 200 will be referred to as a substrate 9.

FIG. 7 is a diagram illustrating the gas supply areas partitioned by the partition plates (dividing structures) 53, 54, 55, and 56 and the period in which the substrate 200 passes through the respective areas so that the relationship can be understood.

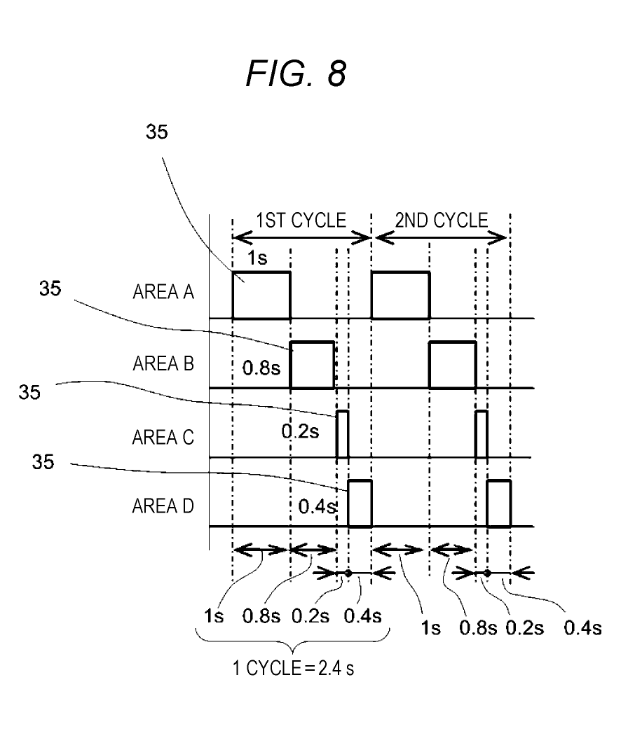

FIG. 8 is a timing chart illustrating the timing at which gas is supplied to the substrate. A case where the periods in which the substrate passes through the respective gas supply areas are different (that is, a case where the periods in which the substrate is exposed to gas in the respective gas supply areas are different) will be considered.

In the present embodiment, for example, a period in which the substrate 200 passes through the gas supply area A between the partition plates 53 and 54 (that is, a processing period of the substrate 200 in the gas supply area A) is set to 1 s. A period in which the substrate 200 passes through the gas supply area B between the partition plates 54 and 55 (that is, a processing period of the substrate 200 in the gas supply area B) is set to 0.8 s. A period in which the substrate 200 passes through the gas supply area C between the partition plates 55 and 56 (that is, a processing period of the substrate 200 in the gas supply area C) is set to 0.2 s. A period in which the substrate 200 passes through the gas supply area D between the partition plates 56 and 53 (that is, a processing period of the substrate 200 in the gas supply area D) is set to 0.4 s.

The ratio of these processing periods is 5:4:1:2. For angles of the gas supply areas A to D, when the entire area (360°) is divided by the ratio of the processing periods in the respective gas supply areas, the gas supply area A has 150°, the gas supply area B has 120°, the gas supply area C has 30°, and the gas supply area D has 60°. In this manner, the angle between the adjacent dividing structures with the gas supply area interposed is set to an angle proportional to the passing period of the substrate in each gas supply area.

FIG. 8 illustrates the gas supply areas A to D divided by the partition plates 53 to 56 so that the positions of the partition plates are adjusted so that a surplus processing period in each area is eliminated. By doing so, the substrate can pass through the respective areas for a period ideal for the processing period in each area. As a result, in the present embodiment, the period for one rotation (one cycle) can be reduced to 2.4 s. Thus, it is possible to shorten the period by 1.6 s as compared to the period 4 s taken for one cycle as in Comparative Example described later. As a result, since the rotation speed of the rotating tray 20 can be accelerated to 25 rpm from 15 rpm as in the conventional technique, it is possible to increase the throughput per batch.

In this manner, by dividing 360° by the ratio of the processing periods in the respective gas supply areas to set the angle θ (rotation angle) between the gas supply areas (that is, the angle between the dividing structures) appropriately, it is possible to eliminate a surplus processing period to minimize (optimize) the processing period for one cycle.

When another type of film is formed, the angle between the dividing structures is set so as to match the processing conditions for forming the other type of film and the lid of the dividing structures is replaced. With such a structure, it is possible to cope with various types of films and the processes for forming various types of films just by replacing the lid.

Naturally, although the rotation angle of each area is set to an angle between the center of the thickness of the partition plates for the respective areas and the center of the adjacent partition plate, an angle between a side surface of a partition plate and a side surface of an adjacent partition plate may be set to the rotation angle.

Moreover, the dividing structures 53, 54, 55, and 56 and the gas supply areas are provided alternately. Since such a structure enables successive processes to be performed, it is possible to increase the throughput.

### (3) Substrate Processing Step

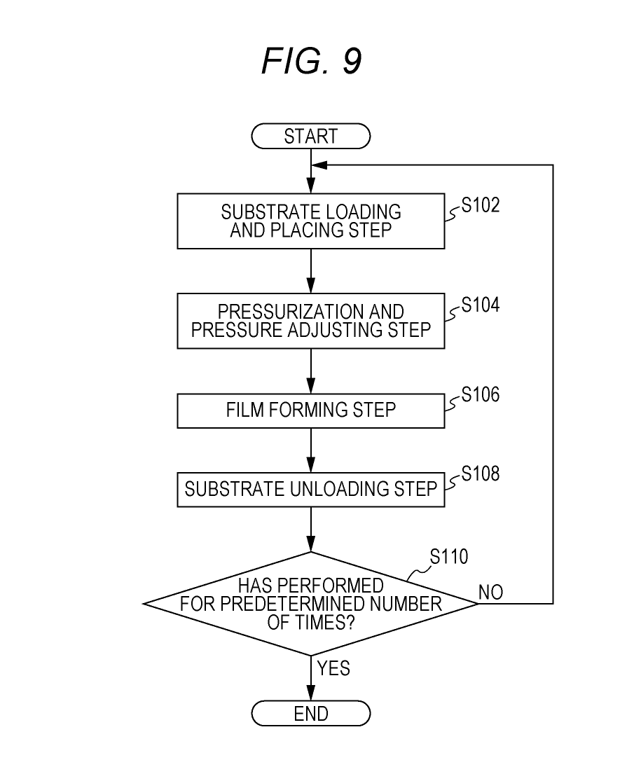

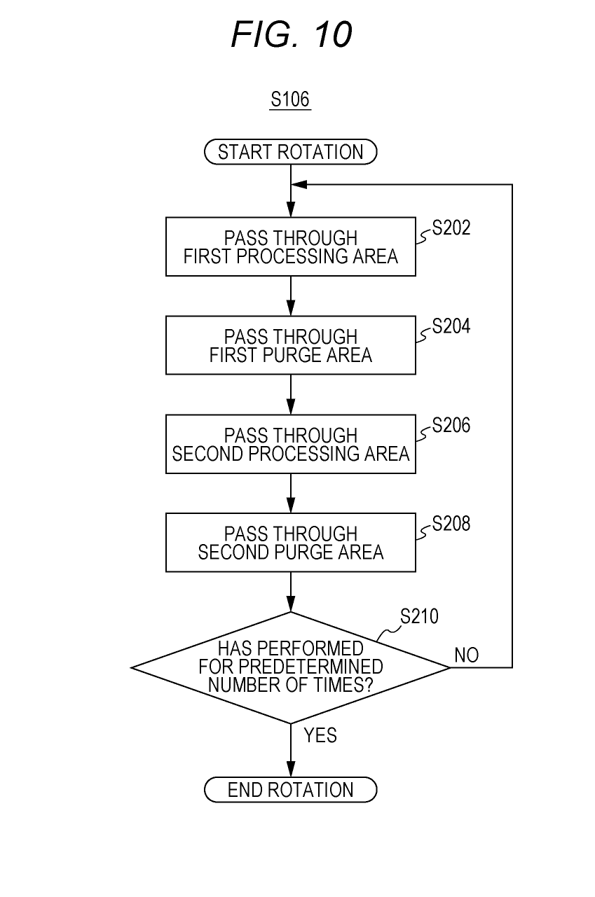

Subsequently, as one of the semiconductor manufacturing steps according to the first embodiment, a substrate processing step that is performed using the process chamber 202b that includes the reaction container 203 will be described with reference to FIGS. 9 and 10. FIG. 9 is a flowchart illustrating a substrate processing step according to the first embodiment, and FIG. 10 is a flowchart illustrating the processes on the substrate in a film forming step in the substrate processing step according to the first embodiment. In the following description, the operations of the constituent components of the process chamber 202 of the substrate processing apparatus 100 are controlled by the controller 221.

In this example, a case where a silicon oxide film (SiO₂ film, hereinafter referred to as a SiO film) as an insulation film is formed on the substrate 200 using trisilylamine (TSA) which is a silicon-containing gas as a first processing gas and using an oxygen gas which is an oxygen-containing gas as a second processing gas will be described.

### (Substrate Loading and Placing Step (S102))

First, the substrate lifting pins 266 are moved up to a transfer position of the substrate 200, and the substrate lifting pins 266 pass through the through-holes 217a of the susceptor 217. As a result, a state where the substrate lifting pins 266 protrude from the surface of the susceptor 217 by a predetermined height is created. Subsequently, the gate valve 244a is opened, and a predetermined number of (for example, five) substrates 200 are loaded into the reaction container 203 using a first substrate transferring and mounting machine 112. The substrates 200 are mounted on the same surface of the susceptor 217 so that the substrates 200 do not overlap each other about the rotation shaft (not illustrated) of the susceptor 217. Due to this, the substrates 200 are horizontally supported on the substrate lifting pins 266 that protrude from the surface of the susceptor 217.

When the substrates 200 are loaded into the reaction container 203, the first substrate transferring and mounting machine 112 is moved outside the reaction container 203, and the gate valve 244a is closed to hermetically seal the reaction container 203. Subsequently, the substrate lifting pins 266 are moved down so that the substrates 200 are mounted on mounting portions 217b provided on the susceptor 217 on the bottom surfaces of the first processing area 201a, the first purge area 204a, the second processing area 201b, and the second purge area 204b.

Moreover, when the substrates 200 are loaded into the reaction container 203, it is preferable to supply N₂ gas as a purge gas from the inert gas supply unit into the reaction container 203 while exhausting the inside of the reaction container 203 using the exhaust unit. That is, it is preferable to supply N₂ gas into the reaction container 203 by operating the vacuum pump 246 to open the APC valve 243 and opening at least the valve 235c of the first inert gas supply unit while exhausting the inside of the reaction container 203. In this way, it is possible to suppress particles from entering into the processing area 201 and suppress particles from adhering onto the substrates 200. Here, inert gas may be supplied from the second and third inert gas supply units. The vacuum pump 246 operates constantly until at least the substrate loading and placing step (S102) to a substrate unloading step (S112) described later end.

### (Temperature and Pressure Adjusting Step (S104))

Subsequently, electric power is supplied to the heater 218 that is embedded in the susceptor 217 to heat the surface of the substrate 200 to a predetermined temperature (for example, 200° C. or higher and 400° C. or lower). In this case, the temperature of the heater 218 is adjusted by controlling the conduction state of the heater 218 based on the temperature information detected by the temperature sensor 274.

Moreover, in the process of heating the substrate 200 formed of silicon, when the surface temperature is heated to 750° C. or higher, impurities may be diffused into a source region or a drain region that is formed in the surface of the substrate 200 to deteriorate the circuit properties, and the performance of a semiconductor device may be degraded. By restricting the temperature of the substrate 200 as described above, diffusion of impurities into the source area or the drain area that is formed in the surface of the substrate 200, the deterioration of the circuit properties, and the degradation in the performance of a semiconductor device can be suppressed.

Moreover, the inside of the reaction container 203 is evacuated by the vacuum pump 246 so that the internal pressure of the reaction container 203 becomes a desired pressure (for example, 0.1 Pa to 300 Pa, and preferably, 20 Pa to 40 Pa). In this case, the internal pressure of the reaction container 203 is measured by a pressure sensor (not illustrated), and the degree of the opening of the APC valve 243 is feedback-controlled based on the measured pressure information.

Moreover, the rotating mechanism 267 is operated to start the rotation of the susceptor 217 while heating the substrate 200. In this case, the rotation speed of the susceptor 217 is controlled by the controller 221. When the susceptor 217 rotates, the substrate 200 starts moving through the first processing area 201a, the first purge area 204a, the second processing area 201b, and the second purge area 204b in that order, and the substrate 200 passes through the respective areas.

### (Film Forming Step (S106))

Next, the film forming step will be described by way of an example of a step of supplying a TSA gas as the first processing gas into the first processing area 201a, supplying an oxygen gas as the second processing gas into the second processing area 201b, and forming a SiO film on the substrate 200. In the following description, the TSA gas, the oxygen gas, and the inert gas are supplied to the respective areas in parallel. In other words, the supply of the TSA gas, the oxygen gas, and the inert gas is performed continuously at least until the process on the substrate is completed.

When the substrate 200 is heated to a desired temperature and the susceptor 217 reaches a desired rotation speed, at least the valves 235a, 235b, and 235c are opened simultaneously, and a processing gas and an inert gas are supplied to the processing areas 201 and the purge areas 204.

That is, the valve 235a is opened to supply the TSA gas into the first processing area 201a, and the valve 235b is opened to supply the oxygen gas into the second processing area 201b, whereby the processing gas is supplied from the processing gas supply unit. Further, the valve 235c is opened to supply the N₂ gas which is an inert gas into the first and second purge areas 204a and 204b, whereby the inert gas is supplied from the inert gas supply unit.

The amount of processing gas supplied is adjusted so that the amount of inert gas mixed into the gas supplied to the first and second processing areas 201a and 201b does not affect substrate processing. By doing so, since the inert gas will not disturb a reaction with the film formed on the substrate 200 and the supplied gas during the substrate processing in the processing areas, it is possible to increase the film forming speed as compared to a case where the inert gas is supplied to the processing areas.

In this case, the APC valve 243 is controlled appropriately so that the internal pressure of the reaction container 203 falls within a range of 10 Pa to 1000 Pa, for example. In this case, the temperature of the heater 218 is set such that the temperature of the substrate 200 falls within a range of 200° C. to 400° C., for example.

When the pressure is adjusted, the valve 235a is opened to exhaust the gas from the exhaust pipe 231 while supplying the TSA gas from the first gas supply pipe 232a into the first processing area 201a through the first gas introduction mechanism 251 and the first gas injection hole 254. In this case, the mass flow controller 232c is controlled so that the flow rate of the TSA gas reaches a predetermined flow rate. The supply flow rate of the TSA gas controlled by the mass flow controller 232c is set to be within a range of 100 sccm to 5000 sccm, for example.

Moreover, the valve 235b is opened to exhaust the gas from the exhaust pipe 231 while supplying the oxygen gas from the second gas supply pipe 233a into the second processing area 201b through the second gas introduction mechanism 252 and the second gas injection hole 255. In this case, the mass flow controller 233c is controlled so that the flow rate of the oxygen gas reaches a predetermined flow rate. The supply flow rate of the oxygen gas controlled by the mass flow controller 233c is set to be within a range of 1000 sccm to 10000 sccm, for example.

Moreover, the valves 235a, 235b, and 235c are opened to exhaust gas while supplying the N₂ gas which is an inert gas as a purge gas from the first inert gas supply pipe 234a into the first and second purge areas 204a and 204b through the inert gas introduction mechanism 253, the first inert gas injection hole 256, and the second inert gas injection hole 257. In this case, the mass flow controller 234c is controlled so that the flow rate of the N₂ gas reaches a predetermined flow rate. Since the inert gas is injected from the first and second purge areas 204a and 204b into the first and second processing areas 201a and 201b through the gap between the end portions of the partition plates 205 and the side wall of the reaction container 203, it is possible to suppress the processing gas from entering into the first and second purge areas 204a and 204b.

Simultaneously with the start of the gas supply, high-frequency power is supplied from the high-frequency power supply 209 to the plasma generating unit 206 provided above the second processing area 201b. The oxygen gas which has been supplied into the second processing area 201b and has passed through the portion under the plasma generating unit 206 changes into a plasma in the second processing area 201b, and active species included in the plasma are supplied to the substrate 200.

Although the oxygen gas reacts at a high temperature, and is thus difficult to react at the processing temperature of the substrate 200 and the pressure in the reaction container 203 as described above, when the oxygen gas is changed into a plasma as in the first embodiment and the active species included therein are supplied, a film forming process can be performed in a range of temperatures of 400° C. or lower, for example. Moreover, when the processing temperatures required for the first and second processing gases are different, the heater 218 may be controlled based on the temperature of the processing gas having the lower processing temperature and the other processing gas of which the processing temperature needs to be increased may be supplied as a plasma. By using a plasma in this manner, it is possible to process the substrate 200 at a low temperature and to suppress thermal damage to the substrate 200 having wires made from aluminum or the like that is vulnerable to heat, for example. Moreover, it is possible to suppress the production of foreign substance such as a product material due to the incomplete reaction of the processing gas and to improve the uniformity or withstand voltage properties of a thin film formed on the substrate 200. Moreover, due to the high oxidizing power of the oxygen gas in the plasma state, it is possible to improve the productivity of the substrate processing such as to shorten an oxidation treatment time.

As described above, when the susceptor 217 rotates, the substrate 200 is repeatedly moved through the first processing area 201a, the first purge area 204a, the second processing area 201b, and the second purge area 204b in that order. In this case, for example, as illustrated in FIG. 7, it is set such that a portion of the susceptor passes through the first processing area 201a in 1 second, the first purge area 204a in 0.8 second, the second processing area 201c in 0.2 second, and the second purge area in 0.4 second.

When the susceptor passes through the respective areas, as illustrated in FIG. 10, the supply of TSA gas, the supply (purge) of N₂ gas, the supply of plasma oxygen gas, and the supply (purge) of N₂ gas are alternately performed on the substrate 200 for a predetermined number of times. Here, the details of the sequence of the film forming process will be described with reference to FIG. 10.

### (Pass Through First Processing Area (S202))

First, the TSA gas is supplied to the surface of the substrate 200 having passed through the first processing area 201a and a portion of the susceptor 217 on which the substrate is not mounted, and a silicon-containing layer is formed on the substrate 200. Gas is injected in the horizontal direction to the first processing area 201a from the first processing gas introduction mechanism 251 through the first gas injection hole 254.

### (Pass Through First Purge Area (S204))

Subsequently, the substrate 200 on which the silicon-containing layer is formed passes through the first purge area 204a. In this case, the N₂ gas which is an inert gas is supplied to the substrate 200 that passes through the first purge area.

### (Pass Through Second Processing Gas Area (S206))

Subsequently, the oxygen gas is supplied to the substrate 200 having passed through the second processing area 201b and the portion of the susceptor 217 where the substrate is not mounted. A silicon oxide layer (SiO layer) is formed on the substrate 200. That is, the oxygen gas reacts with at least a portion of the silicon-containing layer formed on the substrate 200 in the first processing area 201a. As a result, the silicon-containing layer is oxidized and modified into a SiO layer that includes silicon and oxygen. Gas is injected in the horizontal direction to the second processing area 201b from the second processing gas introduction mechanism 252 through the second gas injection hole 255.

### (Pass Through Second Purge Area (S208))

The substrate 200 on which the SiO layer is formed in the second processing area 201b passes through the second purge area 204b. In this case, the N₂ gas which is an inert gas is supplied to the substrate 200 that passes through the second purge area 204b.

### (Check Number of Cycles (S210))

In this manner, by performing one cycle which is one rotation of the susceptor 217 at least once (that is, by passing the substrate 200 through the first processing area 201a, the first purge area 204a, the second processing area 201b, and the second purge area 204b at least once), it is possible to form a SiO film having a predetermined thickness on the substrate 200.

In this step, it is checked whether the cycle has been performed for a predetermined number of times.

When the cycle is performed for a predetermined number of times, it is determined that the thickness has reached a predetermined thickness, and the film forming process ends. When the cycle has not been performed for a predetermined number of times, it is determined that the thickness has not reached a predetermined thickness, and the flow returns to step S202 and the cycle process is continued.

In step S210, after the cycle is performed for a predetermined number of times and it is determined that the SiO film having a desired thickness is formed on the substrate 200, at least the valves 235a and 235b are closed to stop the supply of the TSA gas and the oxygen gas to the first and second processing areas 201a and 201b. In this case, the supply of electric power to the plasma generating unit 206 is stopped. Further, the amount of electric power supplied to the heater 218 is controlled to decrease the temperature or the supply of electric power to the heater 218 is stopped. Further, the rotation of the susceptor 217 is stopped.

### (Substrate Unloading Step (S108))

When the film forming step 106 ends, the substrate is unloaded in the following manner. First, the substrate lifting pins 266 are moved up so that the substrate 200 is supported on the substrate lifting pins 266 that protrude from the surface of the susceptor 217. Moreover, the gate valve 244a is opened to unload the substrate 200 to the outside of the reaction container 203 using the first substrate transferring and mounting machine 112, and the substrate processing step according to the first embodiment ends. The processing conditions such as the temperature of the substrate 200, the internal pressure of the reaction container 203, the flow rates of the gases, the electric power applied to the plasma generating unit 206, and the processing period are optionally adjusted according to the material and the thickness of the film to be modified.

### Other Embodiment of the Present Invention

A second embodiment will be described with reference to FIG. 7.

In this embodiment, a susceptor (also referred to as a rotating tray or a rotating mechanism) 20 rotates at an angular velocity ω corresponding to the ratio of processing periods in the respective areas of the gas supply areas A to D. Further, a period in which a certain point (for example, a central point) of a substrate 9 passes through an n-th gas supply area is tn, and the angle of the n-th gas supply area is θn. In this case, if the susceptor makes one rotation in a period T, θn can be expressed by a product of the angular velocity ω and the processing period tn. By doing so, since the gas supply area can be set with good reproducibility according to the processing period corresponding to the type of processing gas, it is possible to reduce a surplus processing period and to increase the throughput even when the process is changed to a different process.

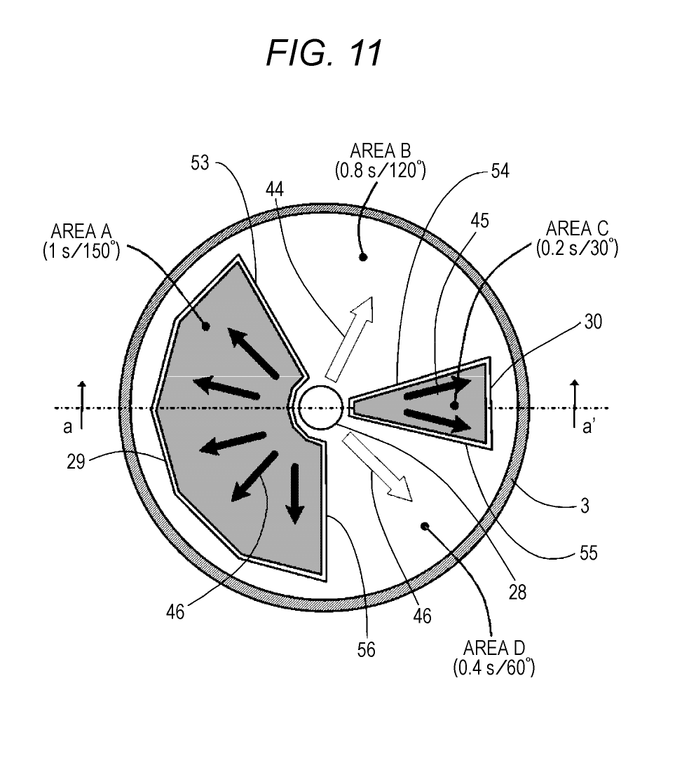

FIG. 11 illustrates a case where the processing area is formed as a shower head. The gas supply area A is formed of a shower head 29 that includes the partition plates 53 and 56, the gas supply area B is formed of a region interposed between the partition plates 53 and 54, the gas supply area C is formed of a shower head 30 that includes the partition plates 54 and 55, and the gas supply area D is formed of a region interposed between the partition plates 55 and 56. When such a shower head is used, since the distance between the substrate and the small holes for injection gas is small, it is possible to perform the process more uniformly.

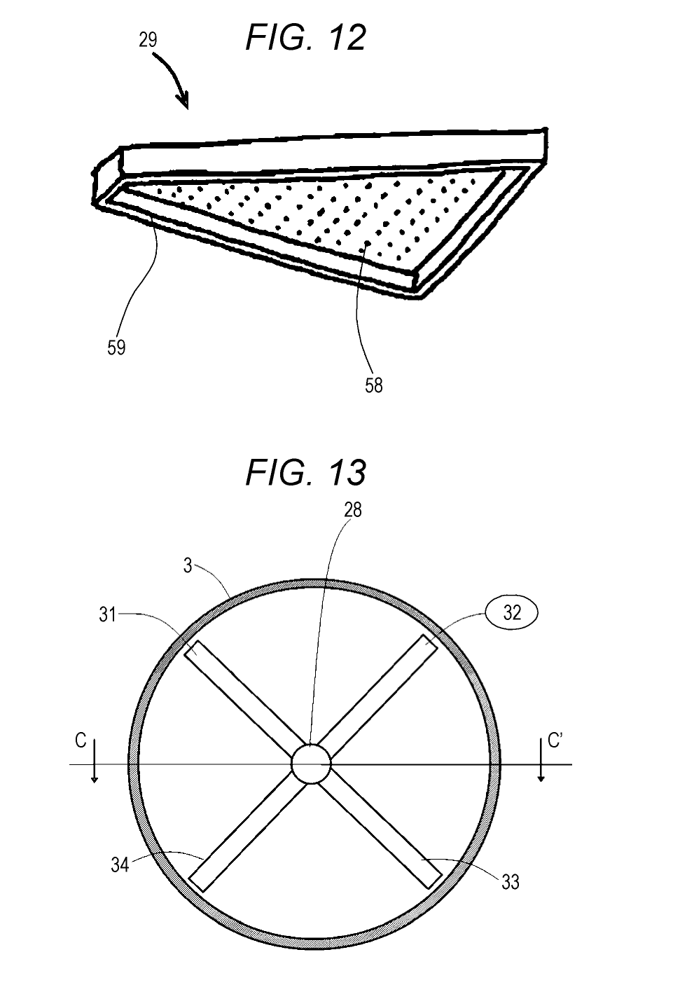

FIG. 12 is a perspective view of the shower head 29 as viewed from the lower side. The processing gas is supplied from a plurality of small holes 58. The partition plate 59 is provided so as to surround the plurality of small holes 58 of the shower head 29 in order to suppress the leakage of the processing gas.

In this manner, by changing the positions of the partition plates that form the gas supply areas in the reaction chamber and changing the size of the plurality of gas supply areas, it is possible to reduce a surplus processing period in each area and to improve the substrate processing performance.

While the embodiments of the present invention have been described in detail, the present invention is not limited to the above embodiments and various modifications can be made without departing from the spirit thereof.

In the present embodiment, although four dividing structures are used, the number is not limited to this, but may be larger than 4 as long as the dividing structures can cope with the type of film to be formed and the process.

Moreover, in the present embodiment, although the partition plates are used as the dividing structures, the dividing structures may have an optional structure if gases do not mix with each other between the adjacent processing gas supply areas. For example, a structure in which the height of the gas supply area is decreased to increase the flow rate of the purge gas and a structure in which a purge gas exhaust unit is provided to create the flow of gas so as not to mix with the processing gas may be used.

Moreover, in the present embodiment, although the angles between the plurality of dividing structures with the gas supply area interposed are fixed, the present invention is not limited to this, and the angle may be variable, for example. With such a structure, it is possible to change the sizes of the gas supply areas after mounting and to adjust the gas supply period to the substrate in the respective gas supply areas.

Moreover, in the case where the angles between the dividing structures are variable, the angles of all dividing structures having the gas supply area interposed may be individually adjustable. With such a structure, the process can be performed flexibly in the respective gas supply areas. Moreover, the angle between the dividing structures of a target gas supply area only can be adjusted, and when the angle between the adjustment target dividing structures is changed, it is possible to form a gas supply area of which the size is changed and a gas supply area of which the size is not changed. In other words, it is possible to adjust the substrate passing period in the target gas supply area only without changing the substrate passing period in the other gas supply areas that are not affected even when the angle of the dividing structures is changed.

Next, Comparative Example of the present embodiment will be described.

A conventional single-wafer apparatus will be described with reference to FIGS. 13 to 15.

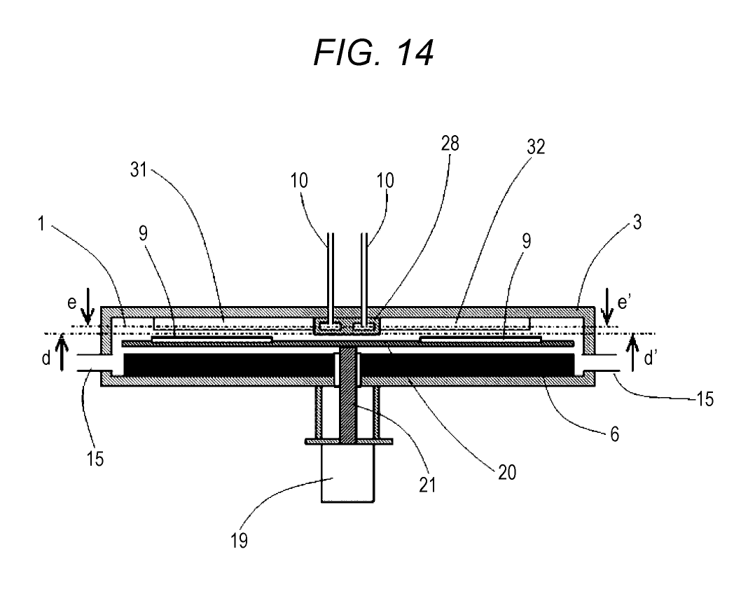

FIGS. 13 and 14 illustrate a cross-section of an apparatus that forms a thin film on the surfaces of a plurality of substrates 9 placed on a rotating tray 20 while rotating the tray 20 (substrate mounting table).

FIG. 13 is a view taken along line d-d′ of FIG. 14, illustrating the structure of an upper side of a reaction chamber 1 as seen from the side of the rotating tray 20, and FIG. 14 is a view taken along line c-c′ of FIG. 13, illustrating the rotating tray 20, the heater 6, and the like included in the reaction chamber 1.

The reaction chamber 1 is configured to be air-tightly sealed by a reaction chamber wall 3, and the heater 6 for heating the substrate 9 on the rotating tray 20 is provided under the reaction chamber 1. The rotating tray 20 is provided above the heater 6 so as to be rotatable, and the rotating tray 20 is rotated when a rotation driving unit 19 drives a rotation shaft 21.

Partition plates 31 to 34 are provided above the reaction chamber 1 in order to divide the processing area, and the gap between the lower surfaces of the partition plates and the rotating tray 20 is narrowed so that different types of gases supplied to the respective processing areas rarely mix with each other. The distance between the partition plates and the rotating tray 20 is set to approximately 1 mm to 3 mm. Gases are supplied to the processing areas in the reaction chamber 1 from a gas supply nozzle 28 provided above the reaction chamber 1. Moreover, gases are supplied from a plurality of gas introduction ports 10 formed in the outer side of the reaction chamber to the gas supply nozzle 28.

An exhaust opening 15 for exhausting the gas introduced into the reaction chamber is formed in the side surface of the reaction chamber 1.

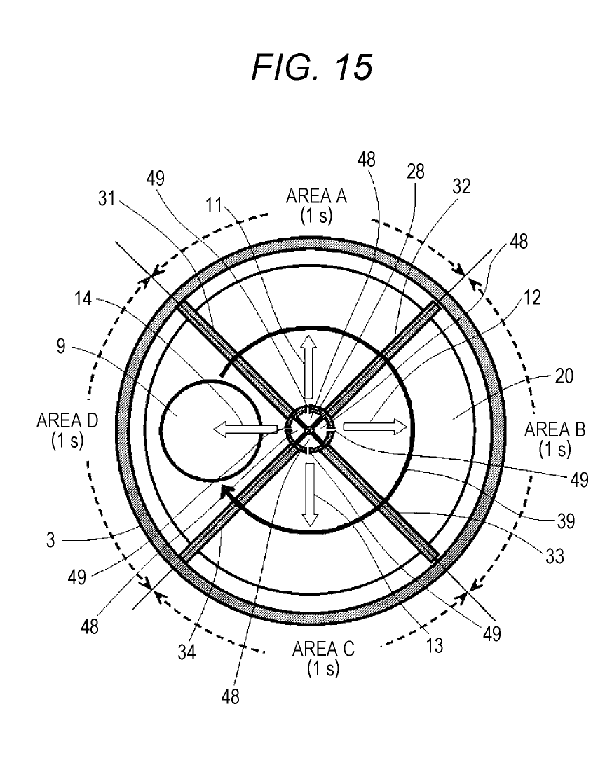

FIG. 15 is a view taken along line e-e′ of FIG. 14 and is a diagram illustrating the gas supply areas partitioned by the partition plates 31 to 34 and the period in which the substrate 9 passes through the respective areas so that the relationship can be understood.

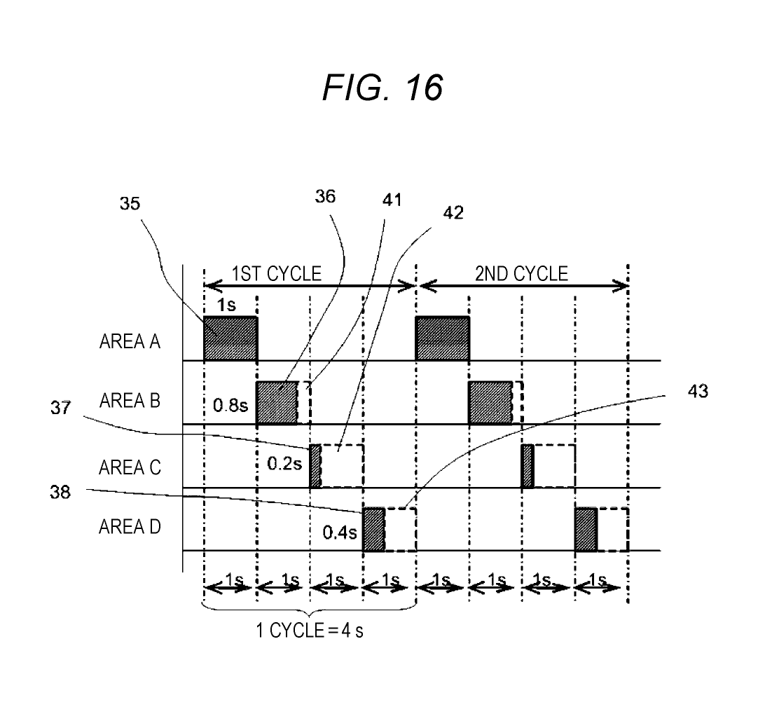

FIG. 16 is a timing chart illustrating the relationship between the processing periods in the respective gas supply areas A to D and the periods in which the substrate 9 passes through the respective gas supply areas. Reference numerals 35, 36, 37, and 38 indicate the periods required for the processing in the respective gas supply areas A, B, C, and D, which are 1 s, 0.8 s, 0.2 s, and 0.4 s, respectively. Moreover, reference numerals 41, 42, and 43 indicate surplus processing periods that are unnecessary for the actual processing in the respective gas supply areas B, C, and D, which are 0.2 s, 0.8 s, and 0.6 s, respectively.

The processing gases introduced from the gas supply ports 10 are supplied to the gas supply areas from small holes 49 via a buffer chamber 48 provided in the gas supply nozzle 28. The processing gas supplied from the small holes 49 flows in the directions indicated by gas flows 11 to 14 and is exhausted from an exhaust opening.

In FIG. 15, the substrate 9 located in the gas supply area D is processed while moving through the gas supply areas A, B, C, and D in that order while the rotating tray 20 makes one rotation in the direction indicated by arrow 39. However, since the processing periods required for the respective areas are different, the rotation speed of the rotating tray 20 is determined according to the area that requires the longest process.

However, in this Comparative Example, as illustrated in FIG. 15, since the gas supply areas A to D are evenly divided by 90° without corresponding to the required processing period, it is necessary to set the rotation speed of the rotating tray so as to correspond to the longest processing period of the processing periods in the respective areas. In this case, since the processing period in each area needs to be set to 1 second, and thus one rotation (one cycle processing) of the rotating tray 20 requires 4 seconds, the rotation speed of the rotating tray 20 needs to be set to 15 rpm.

In contrast, according to the present embodiment, since the substrate processing period which is one of the processing conditions can be flexibly set in the respective processing areas, it is possible to form a desired film even when the substrate is processed for a different processing period in the respective processing areas.

### Preferred Aspect of the Present Invention

Preferred aspects of the present invention will be noted below.

### (Supplementary Note 1)

According to an aspect of the present invention, there is provided a substrate processing apparatus including:

a substrate mounting portion provided in a process chamber and capable of mounting a plurality of substrates in a circumferential direction;

a rotating mechanism that rotates the substrate mounting portion at a predetermined angular velocity;

dividing structures provided in a radial form from a center of a lid of the process chamber so as to divide the process chamber into a plurality of areas; and

gas supply areas disposed between the adjacent dividing structures, wherein

an angle between the adjacent dividing structures with one gas supply area interposed is set to an angle corresponding to the angular velocity and a period in which a portion of the substrate mounting portion passes through the gas supply area.

### (Supplementary Note 2)

According to another aspect of the present invention, there is provided the substrate processing apparatus according to Supplementary Note 1, wherein the lid has a structure that can be removed.

### (Supplementary Note 3)

According to another aspect of the present invention, there is provided a substrate processing apparatus including:

a substrate mounting portion provided in a process chamber and capable of mounting a plurality of substrates in a circumferential direction;

a rotating mechanism that rotates the substrate mounting portion;

dividing structures provided in a radial form from a center of a lid of the process chamber so as to divide the process chamber into a plurality of areas; and

gas supply areas disposed between the adjacent dividing structures, wherein

an angle between the adjacent dividing structures with one gas supply area interposed is set to an angle that is proportional to periods in which a portion of the substrate mounting portion passes through the gas supply areas.

### (Supplementary Note 4)

According to another aspect of the present invention, there is provided the substrate processing apparatus according to Supplementary Note 3, wherein the periods in which the portion of the substrate mounting portion passes through the gas supply areas are different.

### (Supplementary Note 5)

According to another aspect of the present invention, there is provided the substrate processing apparatus according to Supplementary Note 3 or 4, wherein the lid has a structure that can be removed.

### (Supplementary Note 6)

According to another aspect of the present invention, there is provided a lid mounted on a process chamber having a rotatable substrate mounting portion on which a plurality of substrates is mounted, including:

a circular plate; and

dividing structures that divide the process chamber into a plurality of gas supply areas when mounted on the process chamber and that are provided in a radial form from a center of the circular plate, wherein

an angle between the adjacent dividing structures with one gas supply area interposed is set to an angle corresponding to a period in which a portion of the substrate mounting portion passes through the gas supply area and an angular velocity of rotation of the substrate mounting portion.

### (Supplementary Note 7)

According to another aspect of the present invention, there is provided a method of manufacturing a semiconductor device, including:

loading a plurality of substrates into a process chamber which includes processing areas divided by dividing structures provided in a radial form from a center of a lid of the process chamber and a rotatable substrate mounting portion on which the plurality of substrates is mounted, in which an angle between the adjacent dividing structures with one gas supply area interposed is set to an angle corresponding to the angular velocity and a period in which a portion of the substrate mounting portion passes through the gas supply area;

placing the plurality of substrates on the substrate mounting portion;

supplying gas to the processing areas while rotating the substrate mounting portion; and

unloading the substrate from the process chamber.

What is claimed is:

1. A substrate processing apparatus comprising:
a substrate mounting portion provided in a process chamber and capable of mounting a plurality of substrates in a circumferential direction;
a rotating mechanism that rotates the substrate mounting portion at a predetermined angular velocity;
dividing structures provided in a radial form from a center of a lid of the process chamber so as to divide the process chamber into a plurality of areas; and
gas supply areas disposed between adjacent dividing structures, wherein
an angle between the adjacent dividing structures with one gas supply area interposed is set to an angle corresponding to the angular velocity and a period in which a portion of the substrate mounting portion passes through the gas supply area.

2. The substrate processing apparatus according to claim 1, wherein
a gas introduction mechanism is provided in each of the gas supply areas,
the gas introduction mechanism includes an upstream-side introduction mechanism connected to a gas supply pipe and a downstream-side introduction mechanism that has a gas injection hole, and
the upstream-side introduction mechanism and the downstream-side introduction mechanism being either separated or not separated.

3. The substrate processing apparatus according to claim 2, wherein
a gas guiding unit formed in a radial form is connected to the gas introduction mechanism, and the gas guiding unit is fixed to the lid.

4. The substrate processing apparatus according to claim 2, wherein
the downstream-side introduction mechanism is fixed to the lid.

5. The substrate processing apparatus according to claim 1, wherein
the lid being either separated or not separated from a process chamber wall of the process chamber.

6. The substrate processing apparatus according to claim 5, wherein
a gas introduction mechanism is provided in each of the gas supply areas,
the gas introduction mechanism includes an upstream-side introduction mechanism connected to a gas supply pipe and a downstream-side introduction mechanism that has a gas injection hole, and
the upstream-side introduction mechanism and the downstream-side introduction mechanism being either separated or not separated.

7. A substrate processing apparatus comprising:
a substrate mounting portion provided in a process chamber and capable of mounting a plurality of substrates in a circumferential direction;
a rotating mechanism that rotates the substrate mounting portion;
dividing structures provided in a radial form from a center of a lid of the process chamber so as to divide the process chamber into a plurality of areas; and
gas supply areas disposed between the adjacent dividing structures, wherein
an angle between the adjacent dividing structures with one gas supply area interposed is set to an angle that is proportional to periods in which a portion of the substrate mounting portion passes through the gas supply areas.

8. The substrate processing apparatus according to claim 7, wherein
the periods in which the portion of the substrate mounting portion passes through the gas supply areas are different.

9. The substrate processing apparatus according to claim 8, wherein
the lid being either separated from or not separated from a process chamber wall of the process chamber.

10. The substrate processing apparatus according to claim 9, wherein
a gas introduction mechanism is provided in each of the gas supply areas,
the gas introduction mechanism includes an upstream-side introduction mechanism connected to a gas supply pipe and a downstream-side introduction mechanism that has a gas injection hole, and
the upstream-side introduction mechanism and the downstream-side introduction mechanism being either separated or not separated.

11. The substrate processing apparatus according to claim 7, wherein
the lid can be separated from a process chamber wall of the process chamber.

12. The substrate processing apparatus according to claim 11, wherein
a gas introduction mechanism is provided in each of the gas supply areas,
the gas introduction mechanism includes an upstream-side introduction mechanism connected to a gas supply pipe and a downstream-side introduction mechanism that has a gas injection hole, and
the upstream-side introduction mechanism and the downstream-side introduction mechanism being either separated or not separated.

13. The substrate processing apparatus according to claim 7, wherein
a gas introduction mechanism is provided in each of the gas supply areas,
the gas introduction mechanism includes an upstream-side introduction mechanism connected to a gas supply pipe and a downstream-side introduction mechanism that has a gas injection hole, and
the upstream-side introduction mechanism and the downstream-side introduction mechanism being either separated or not separated.

14. A method of manufacturing a semiconductor device, comprising:
loading a plurality of substrates into a process chamber which includes processing areas divided by dividing structures provided in a radial form from a center of a lid of the process chamber and a rotatable substrate mounting portion on which the plurality of substrates is mounted, in which an angle between the adjacent dividing structures with one gas supply area interposed is set to an angle corresponding to the angular velocity and a period in which a portion of the substrate mounting portion passes through the gas supply area;
placing the plurality of substrates on the substrate mounting portion;
supplying gas to the processing areas while rotating the substrate mounting portion; and
unloading the substrate from the process chamber.
